(19) United States
(12) Patent Application Publication
(10) Pub. No.: US 2026/0223290 A1
(43) Pub. Date: Jul. 30, 2026

(54) WIRING SUBSTRATE AND METHOD OF MANUFACTURING THE WIRING SUBSTRATE

(71) Applicant: SHINKO ELECTRIC INDUSTRIES CO., LTD., Nagano-shi (JP)

(72) Inventors: Naotaka Noguchi, Nagano (JP); Naoyuki Kanda, Nagano (JP)

(21) Appl. No.: 19/454,686

(22) Filed: Jan. 21, 2026

(30) Foreign Application Priority Data
Jan. 29, 2025 (JP) 2025-013264

(51) Int. Cl. H05K 1/11

(52) U.S. Cl. CPC H05K 1/115; H05K 2201/09227; H05K 2201/09563

(57) ABSTRACT

A wiring substrate includes a wiring layer and an insulating layer. The wiring layer includes a conductor pattern, and a plurality of wiring patterns that are formed side by side in a predetermined area sandwiched between a pair of conductor patterns and that have a smaller occupied area than the conductor pattern. The insulating layer is laminated on the wiring layer. Among the plurality of wiring patterns, the heights of the wiring patterns that are arranged at a central portion of the predetermined area are lower than the heights of the wiring patterns that are arranged at both end portions of the predetermined area.

### CROSS-REFERENCE TO RELATED APPLICATION

This application is based upon and claims the benefit of priority of the prior Japanese Patent Application No. 2025-013264, filed on January 29, 2025, the entire contents of which are incorporated herein by reference.

### FIELD

The embodiment discussed herein is related to a wiring substrate and a method of manufacturing the wiring substrate.

### BACKGROUND

Conventionally, for example, a wiring substrate on which, for example, a semiconductor chip is mounted may have a multi-layer wiring structure that is formed by using, for example, a semi-additive process. Specifically, a wiring layer is formed on an insulating layer by performing electroless plating and electrolytic plating, and furthermore, an insulating layer that covers the wiring layer is laminated on this wiring layer. In this way, by repeatedly laminating the insulating layer and the wiring layer, the wiring substrate having the multi-layer wiring structure is formed.

In the wiring layer formed in the multi-layer wiring structure, both of a conductor pattern that has a relatively large occupied area and a plurality of wiring patterns that are sandwiched by a pair of the conductor patterns and that have a relatively small occupied area are included.

Patent Literature 1: Japanese Laid-open Patent Publication No. 2013-30516

However, in the conventional wiring substrate, there is a problem in that the thickness of the insulating layer that covers the wiring layer varies. Specifically, the occupied area of the plurality of wiring patterns that are included in the wiring layer is smaller than the occupied area of the conductor pattern, so that, when the insulating layer that covers the wiring layer is laminated on the wiring layer, the insulating layer that is in a semi cured state is likely to be filled into a gap between the adjacent wiring patterns. As a result of this, a top surface of the insulating layer that is located at an upper part of the plurality of wiring patterns is lower than the top surface of the insulating layer that is located at an upper part of the conductor pattern, and accordingly, a variation occurs in the thickness of the insulating layer that covers the wiring layer.

### SUMMARY

According to an aspect of an embodiment, a wiring substrate includes a wiring layer that includes a conductor pattern, and a plurality of wiring patterns that are formed side by side in a predetermined area sandwiched between a pair of the conductor patterns and that have a smaller occupied area than the conductor pattern; and an insulating layer that is laminated on the wiring layer, wherein, among the plurality of wiring patterns, heights of the wiring patterns that are arranged at a central portion of the predetermined area are lower than heights of the wiring patterns that are arranged at both end portions of the predetermined area.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a diagram illustrating a configuration of a wiring substrate according to an embodiment;

FIG. 2 is a diagram illustrating an enlarged view of a wiring layer that is constituted in a multi-layer wiring structure;

FIG. 3 is a diagram illustrating a state in which an insulating layer is laminated on a wiring layer according to a comparative example;

FIG. 4 is a diagram illustrating a state in which the insulating layer is laminated on the wiring layer according to the embodiment;

FIG. 5 is a flowchart illustrating a method of manufacturing a semiconductor device according to the embodiment;

FIG. 6 is a diagram illustrating a specific example of a core substrate forming step;

FIG. 7 is a diagram illustrating a specific example of a buildup step;

FIG. 8 is a diagram illustrating a specific example of a solder resist layer forming step;

FIG. 9 is a diagram illustrating a specific example of a connection terminal forming step;

FIG. 10 is a diagram illustrating a specific example of a semiconductor chip mounting step;

FIG. 11 is a flowchart illustrating a wiring layer forming step according to the embodiment;

FIG. 12 is a diagram illustrating a specific example of a seed layer forming step;

FIG. 13 is a diagram illustrating a specific example of an image development step;

FIG. 14 is a diagram illustrating a specific example of a plating step; and

FIG. 15 is a diagram illustrating a specific example of an etching step.

### DESCRIPTION OF EMBODIMENT

Hereinafter, a preferred embodiment of a wiring substrate and a method of manufacturing the wiring substrate disclosed in the present application will be described in detail below with reference to the accompanying drawings. Furthermore, the disclosed technology is not limited by the embodiment.

### Embodiment

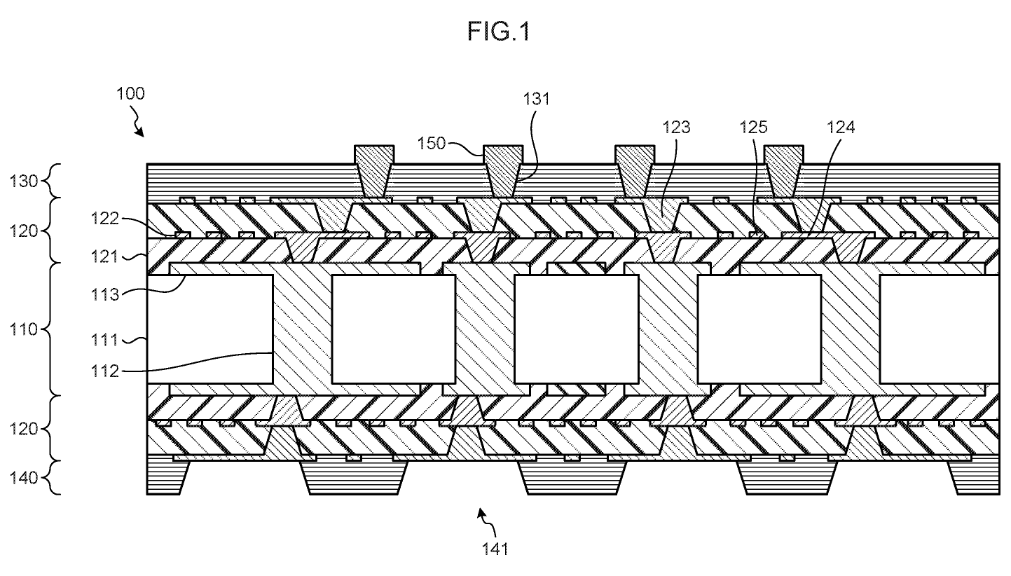

FIG. 1 is a diagram illustrating a configuration of a wiring substrate 100 according to an embodiment. In FIG. 1, a cross section of the wiring substrate 100 is schematically illustrated. The wiring substrate 100 illustrated in FIG. 1 is able to be used as a substrate for a semiconductor device having mounted thereon, for example, a semiconductor chip.

The wiring substrate 100 is constituted to have a laminated structure, and includes a core substrate 110, a multi-layer wiring structure 120, and solder resist layers 130 and 140. In the following, as illustrated in FIG. 1, a description will be given on the assumption that the solder resist layer 140 is a lowermost layer and the solder resist layer 130 is an uppermost layer, but, the wiring substrate 100 may be used by, for example, vertically inverting the surfaces, or may be used in an arbitrary orientation.

The core substrate 110 is constituted such that a wiring layer 113 is formed on both sides of a base material 111 that is an insulating material having a plate shape by performing metal plating. The both sides of the wiring layer 113 are connected with each other, as needed, by a feedthrough wiring 112 that passes through the base material 111.

The multi-layer wiring structure 120 is constituted to laminate a layer that includes both of an insulating layer 121 that has an insulation property and a wiring layer 122 that has a conductive property. The insulating layer 121 is formed by using, for example, a resin having an insulation property, such as an epoxy resin or a polyimide resin. Furthermore, the wiring layer 122 is formed by using, for example, a metal, such as copper or a copper alloy. In FIG. 1, two layers are laminated in the multi-layer wiring structure 120 that is disposed at an upper part of the core substrate 110, and two layers are laminated in the multi-layer wiring structure 120 that is disposed at a lower part of the core substrate 110, but the number of layers to be laminated may be a single layer or may be three or more layers. The wiring layers 113 and 122 that are adjacent to each other via the insulating layer 121 are connected with each other, as needed, by a via 123 that passes through the insulating layer 121.

In the wiring layer 122, a pad 124 (one example of a conductor pattern) and a plurality of wiring patterns 125 are formed. The pad 124 is connected to the other adjacent wiring layer 122 by way of the via 123. The plurality of wiring patterns 125 are formed in a predetermined area that is sandwiched by a pair of the pads 124, and an occupied area of each of the plurality of wiring patterns 125 is smaller than an occupied area of each of the pads 124. The occupied area mentioned here is, for example, an area that is occupied by the pad 124 or occupied by the plurality of wiring patterns 125 per unit length in the direction parallel to the top surface of the insulating layer 121. As will be described later, the height of each of the plurality of wiring patterns 125 decreases in accordance with a direction from both end portions of the predetermined area toward the central portion of the predetermined area.

The solder resist layer 130 is a layer that covers the wiring layer 122 located at the uppermost layer of the multi-layer wiring structure 120, and that protects the wiring lines. The solder resist layer 130 is a layer that is made of, for example, a photosensitive resin, such as an acrylic resin or a polyimide resin, having the insulation property, and is one of the insulating layers. Moreover, the solder resist layer 130 may be formed by using, for example, a non-photosensitive resin, such as an epoxy resin, having an insulation property.

The solder resist layer 130 side of the wiring substrate 100 is a surface on which, for example, an electronic component, such as a semiconductor chip, is mounted. At the position at which the semiconductor chip is mounted, an opening portion 131 is formed in the solder resist layer 130. In a case where the solder resist layer 130 is formed by using a photosensitive resin, it is possible to form the opening portion 131 by performing a process of exposure and image development. Furthermore, in a case where the solder resist layer 130 is formed by using a non-photosensitive resin, it is possible to form the opening portion 131 by performing a process of laser beam machining. In addition, at the opening portion 131, a connection terminal 150 that connects the wiring layer 122 constituted in the multi-layer wiring structure 120 and electrodes of the semiconductor chip is formed.

The solder resist layer 140 is, similarly to the solder resist layer 130, a layer that covers the wiring layer 122 located at the top surface of the multi-layer wiring structure 120, and that protects the wiring. The solder resist layer 140 is a layer that is made of, for example, a photosensitive resin, such as an acrylic resin or a polyimide resin, having he insulation property, and is one of the insulating layers. Moreover, the solder resist layer 140 may be formed by using, for example, a non- photosensitive resin, such as an epoxy resin, having an insulation property.

The solder resist layer 140 side of the wiring substrate 100 is a surface that is connected to an external component, an external device, or the like. At the position at which the external connection terminal that is electrically connected to the external component or the external device, an opening portion 141 is formed in the solder resist layer 140, and the wiring layer 122 constituted in the multi-layer wiring structure 120 is exposed from the opening portion 141. At the opening portion 141, for example, an external connection terminal, such as a solder ball, is formed. In a case where the solder resist layer 140 is formed by using a photosensitive resin, it is possible to form the opening portion 141 by performing a process of exposure and image development. Furthermore, in a case where the solder resist layer 140 is formed by using a non-photosensitive resin, it is possible to form the opening portion 141 by performing a process of laser beam machining.

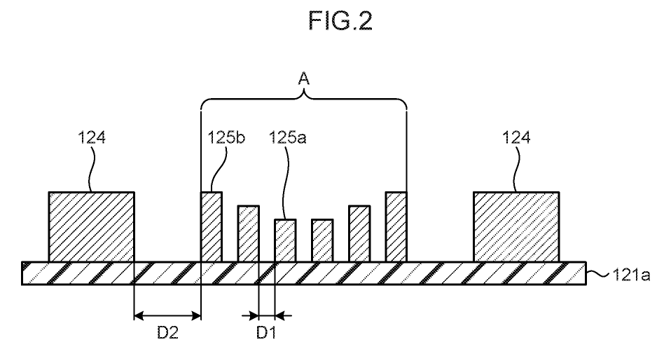

FIG. 2 is a diagram illustrating an enlarged view of the wiring layer 122 that is constituted in the multi- layer wiring structure 120. FIG. 2 illustrates the pair of pads 124 and a plurality of wiring patterns 125a and 125b that are formed on the upper surface of an insulating layer 121a. The plurality of wiring patterns 125a and 125b are formed side by side in a predetermined area A that is sandwiched by the pair of pads 124, and an occupied area of each of the plurality of wiring patterns 125a and 125b is smaller than that of the respective pads 124.

The wiring patterns 125a that are arranged at the central portion of the predetermined area A are lower than the wiring patterns 125b that are arranged at the both end portions of the predetermined area A. In other words, the heights of the plurality of wiring patterns 125 from the upper surface (top surface) of the insulating layer 121a are different, and the height of each of the wiring patterns 125 decreases from the both end portions toward the central portion of the predetermined area A. Furthermore, these wiring patterns 125 are formed at the same time by performing, for example, electrolytic copper plating, so that the heights of the wiring patterns 125 are accordingly different. In other words, by performing electrolytic copper plating at an electric current density that is greater than an electric current density indicated in a case where the heights of the plurality of wiring patterns 125 are the same, the height to which plating grows at each of the wiring patterns 125 is different, so that the wiring patterns 125 each having a different height are formed as a result of the electrolytic copper plating that is performed at the same time.

When the multi-layer wiring structure 120 is formed, a plurality of the insulating layers 121 and the wiring layers 122 may be laminated on each of the upper surface and the lower surface of the core substrate 110. At this time, the occupied area of each of the plurality of wiring patterns 125 included in the wiring layer 122 is smaller than that of the pad 124, so that the insulating layer 121 that is in a semi cured state is likely to be filled into a gap between the adjacent wiring patterns 125.

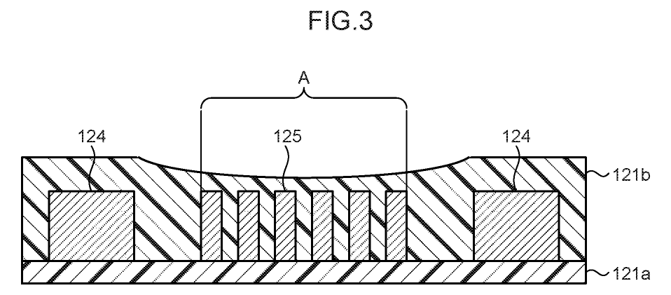

FIG. 3 is a diagram illustrating a state in which an insulating layer 121b is laminated on the wiring layer 122 according to a comparative example. The insulating layer 121b is formed by laminating the insulating resin film that is in the semi cured state on the wiring layer 122, and after that, by heating, pressurizing, and hardening the insulating resin film that is in the semi cured state. The heights of the plurality of wiring patterns 125 that are included in the wiring layer 122 according to the comparative example are the same. In the wiring layer 122 according to the comparative example, as a result of the insulating layer 121b that is in the semi cured state being filled into a gap between the adjacent wiring patterns 125, the top surface of the insulating layer 121b that is located at the upper part of the plurality of wiring patterns 125 is lower than the top surface of the insulating layer 121b that is located at the upper part of the pad 124. At this time, a flow of the insulating layer 121b toward the upper part of the plurality of wiring patterns 125 is blocked by the plurality of wiring patterns 125 that have the same height, so that the thickness of the insulating layer 121b that is located at the plurality of wiring patterns 125 is relatively small.

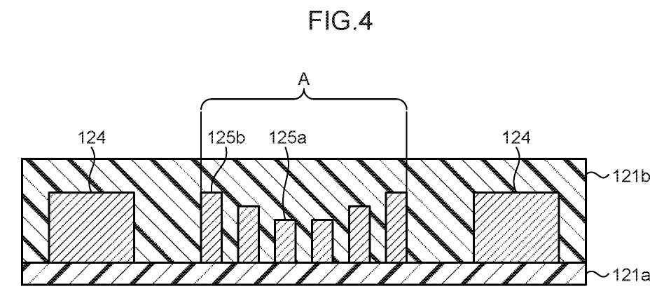

In contrast, as illustrated in FIG. 4, the heights of the plurality of wiring patterns 125 included in the wiring layer 122 according to the embodiment are different, the height of each of the wiring patterns 125 decreases in accordance with a direction from the both end portions toward the central portion of the predetermined area A. FIG. 4 is a diagram illustrating a state in which the insulating layer 121b is laminated on the wiring layer 122 according to the embodiment. In FIG. 4, the insulating layer 121b is formed by laminating the insulating resin film that is in the semi cured state on the wiring layer 122, and after that, by heating, pressurizing, and hardening the insulating resin film that is in the semi cured state. In the wiring layer 122 according to the embodiment, when the insulating layer 121b that is in the semi cured state is filled into a gap between the adjacent wiring patterns 125, a flow of the insulating layer 121b from both end portions toward the central portion included in the predetermined area A occurs at the upper part of the plurality of wiring patterns 125. As a result of this, the flow of the insulating layer 121b from the upper part of the pad 124 toward the upper part of the plurality of wiring patterns 125 is facilitated. As a result of this, it is possible to reduce a decrease in height of the top surface of the insulating layer 121b that is located at the upper part of the plurality of wiring patterns 125, so that it is possible to suppress a variation in thickness of the insulating layer 121b that covers the wiring layer 122.

A description will be given here by referring back to FIG. 2. A distance D1 between the adjacent wiring patterns 125 among the plurality of wiring patterns 125 may be smaller than a distance D2 between each of the wiring pattern 125b that is arranged at both end portions of the predetermined area A and each of the pair of pads 124 that sandwiches the predetermined area A. In this way, by reducing the distance D1 between the adjacent wiring patterns 125, it is possible to reduce an amount of the insulating layer 121b that is in the semi cured state and that is filled into a gap between the adjacent wiring patterns 125, and, as a result of this, it is possible to suppress a variation in thickness of the insulating layer 121b.

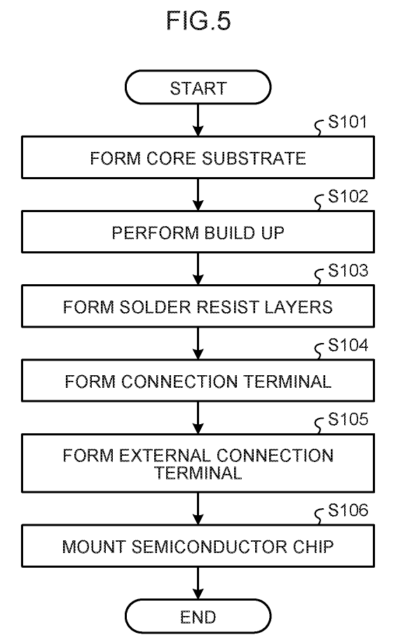

Subsequently, a method of manufacturing a semiconductor device that includes the wiring substrate 100 constituted as described above will be described with reference to FIG. 5 by using specific examples. FIG. 5 is a flowchart illustrating the method of manufacturing the semiconductor device according to the embodiment.

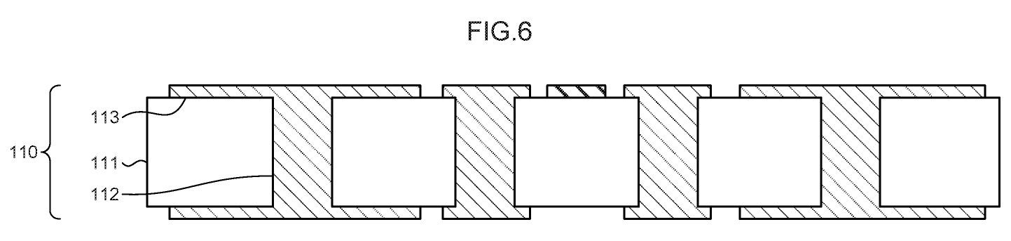

First, the core substrate 110 that serves as a support member of the wiring substrate 100 is formed (Step S101). Specifically, for example, as illustrated in FIG. 6, the feedthrough wiring 112 that passes through the base material 111 is formed on the base material 111 that is an insulating material having a plate shape, and the wiring layer 113 that is made of, for example, a metal, such as copper or a copper alloy, is formed on both sides of the base material 111 by a copper foil or by performing a process of copper plating, for example. FIG. 6 is a diagram illustrating a specific example of a core substrate forming step. The wiring layer 113 that is disposed on both surfaces of the base material 111 is connected, as needed, by the feedthrough wiring 112 that is formed by performing plating on a metal that is made of, for example, copper, a copper alloy, or the like. The base material 111 used may be, for example, a material obtained by impregnating a reinforcement material, such as a glass woven fabric, with an insulating resin, such as an epoxy resin. The reinforcement material used may be, in addition to the glass woven fabric, a glass non-woven fabric, an aramid woven fabric, an aramid non-woven fabric, or the like. Furthermore, in addition to the epoxy resin, the insulating resin used may be a polyimide resin, a cyanate resin, or the like.

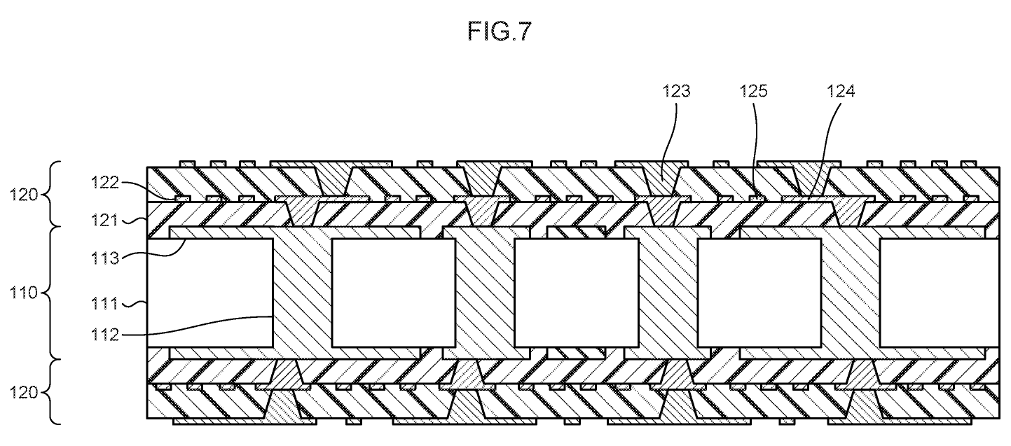

Then, the multi-layer wiring structures 120 are formed on the upper surface and the lower surface of the core substrate 110 by using a buildup technique (Step S102). Specifically, for example, as illustrated in FIG. 7, the insulating layers 121 are formed on the upper surface and the lower surface of the core substrate 110, and the wiring layers 122 are formed on the top surface of the associated insulating layers 121. FIG. 7 is a diagram illustrating a specific example of a buildup step. Each of the insulating layers 121 is formed by using, for example, an insulating resin, such as an epoxy resin or a polyimide resin, having a thermosetting property. For example, each of the insulating layers 121 is formed by laminating the insulating resin film that is in the semi cured state on the wiring layer 122, and after that, by heating, pressurizing, and hardening the insulating resin film that is in the semi cured state. Furthermore, each of the wiring layers 122 is formed by performing plating on a metal made of, for example, copper, a copper alloy, or the like.

A portion between the wiring layer 113 that is included in the core substrate 110 and the wiring layer 122, or a portion between the wiring layer 122 and the adjacent layer is connected, as needed, by the via 123 that is formed by performing plating on, for example, a metal, such as copper or a copper alloy. A plurality of the insulating layers 121 and the wiring layers 122 may be laminated on each of the upper surface and the lower surface of the core substrate 110. In the wiring layer 122 that constitutes the multi-layer wiring structure 120, the pad 124 is formed at a position at which the via 123 is formed, and the plurality of wiring patterns 125 are formed in the predetermined area that is sandwiched by the pair of pads 124. Moreover, a forming step of the wiring layer 122 that constitutes the multi-layer wiring structure 120 will be described in detail later.

When the multi-layer wiring structure 120 has been formed by using the buildup technique, the wiring layer 122 disposed at the top surface of the multi-layer wiring structure 120 is covered by the solder resist layers 130 and 140 (Step S103). In other words, the wiring layer 122 that is disposed at the top surface of the multi-layer wiring structure 120 and that has been laminated on the upper surface of the core substrate 110 is covered by the solder resist layer 130, and the wiring layer 122 that is disposed at the top surface of the multi-layer wiring structure 120 and that has been laminated on the lower surface of the core substrate 110 is covered by the solder resist layer 140.

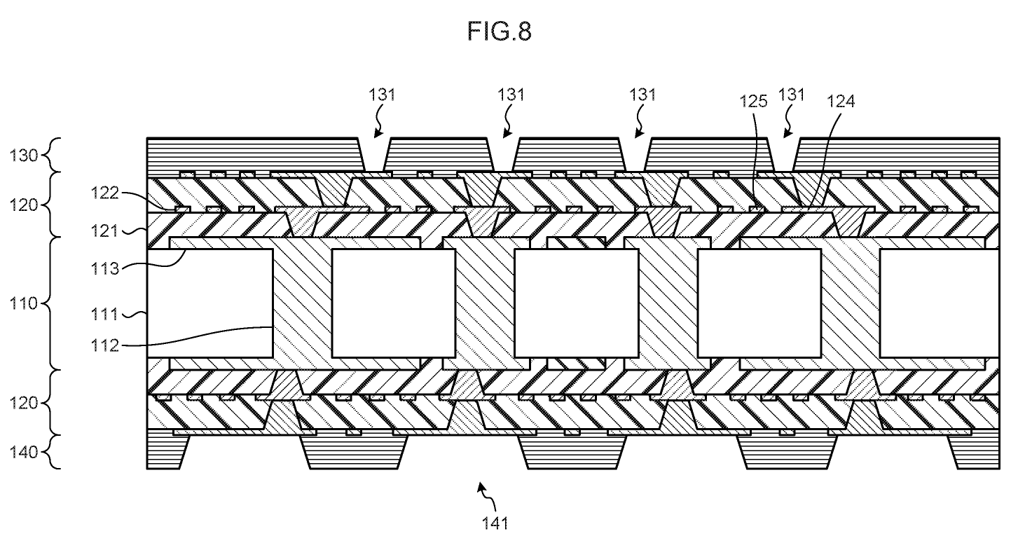

Then, for example, as illustrated in FIG. 8, the opening portion 131 is drilled into the solder resist layer 130 that is disposed on the side, on which the semiconductor chip is mounted, at a position at which the connection terminal for the semiconductor chip is provided. FIG. 8 is a diagram illustrating a specific example of a solder resist layer forming step. The wiring layer 122 disposed on the top surface of the multi-layer wiring structure 120 is exposed from the bottom of the opening portion 131. On the other hand, the opening portion 141 is drilled into the solder resist layer 140 that is disposed on the side, which is connected to the external component or the external device, at a position at which the external connection terminal is provided. The wiring layer 122 disposed on the top surface of the multi-layer wiring structure 120 is exposed from the bottom of the opening portion 141.

In a case where a photosensitive resin is used as the solder resist layers 130 and 140, it is possible to form the opening portions 131 and 141 by performing a process of exposure and image development. Furthermore, in a case where a non-photosensitive resin is used as the solder resist layers 130 and 140, it is possible to form the opening portions 131 and 141 by performing a process of laser beam machining.

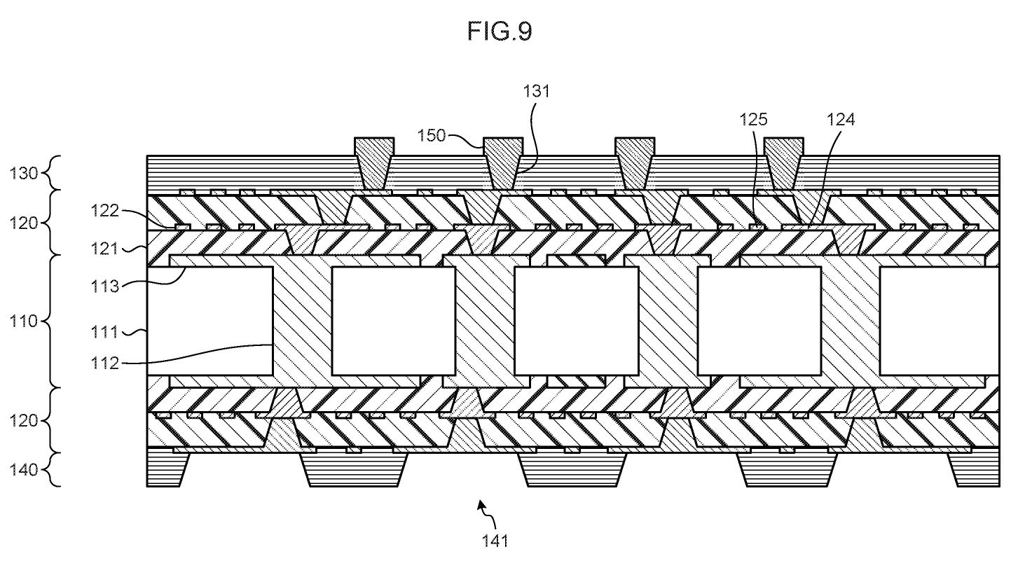

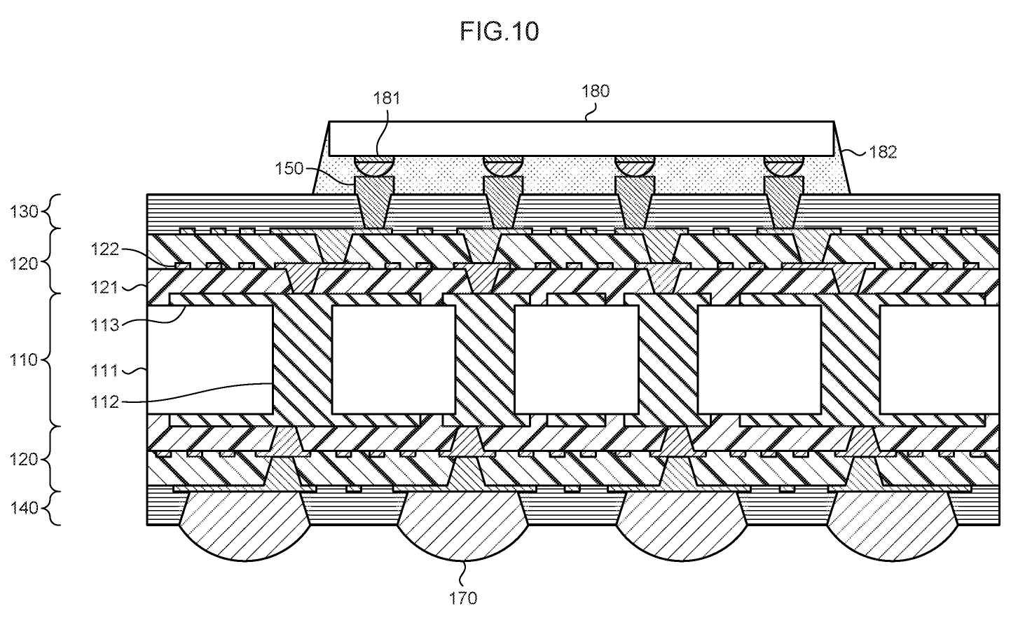

Then, the connection terminal that is used to connect the semiconductor chip is formed at the opening portion 131 disposed at the solder resist layer 130 (Step S104). In other words, for example, as illustrated in FIG. 9, the connection terminal 150 is formed at the opening portion 131 by performing, for example, copper plating. FIG. 9 is a diagram illustrating a specific example of a connection terminal forming step. By performing the steps described above, the wiring substrate 100 illustrated in FIG. 1 has been completed. When the connection terminal 150 has been formed on the solder resist layer 130 side, the external connection terminal is formed on the solder resist layer 140 side (Step S105). Then, the semiconductor chip is mounted on the solder resist layer 130 side (Step S106), and the connection terminals 150 and the electrodes of the semiconductor chip are connected. Specifically, for example, as illustrated in FIG. 10, the external connection terminal, such as a solder ball 170, is formed at the opening portion 141 of the solder resist layer 140. Furthermore, a semiconductor chip 180 is mounted on the upper part of the connection terminal 150, and electrodes 181 disposed on the semiconductor chip 180 are bonded to the respective connection terminals 150 by using, for example, solder or the like. FIG. 10 is a diagram illustrating a specific example of a semiconductor chip mounting step.

After that, the bonding portions between the electrodes 181 and the connection terminals 150 are sealed by an underfill resin 182, and a semiconductor device in which the semiconductor chip 180 is mounted on the wiring substrate 100 is obtained. Moreover, the step of forming the external connection terminal and the step of mounting the semiconductor chip described above may be performed in reverse order. In other words, after the semiconductor chip 180 is mounted on the wiring substrate 100, the external connection terminals, such as the solder balls 170, may be formed at the opening portion 141 that is formed on the solder resist layer 140.

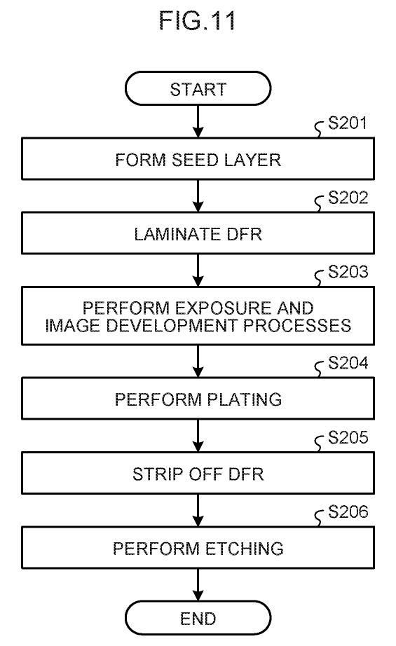

In the following, a forming step of the wiring layer 122 that constitutes the multi-layer wiring structure 120 will be more specifically described with reference to FIG. 11. FIG. 11 is a flowchart illustrating the wiring layer forming step according to the embodiment. Here, a case in which the wiring layer 122 is formed on the upper surface of the insulating layer 121a (see FIG. 2) that is disposed at the upper part of the core substrate 110 will be described.

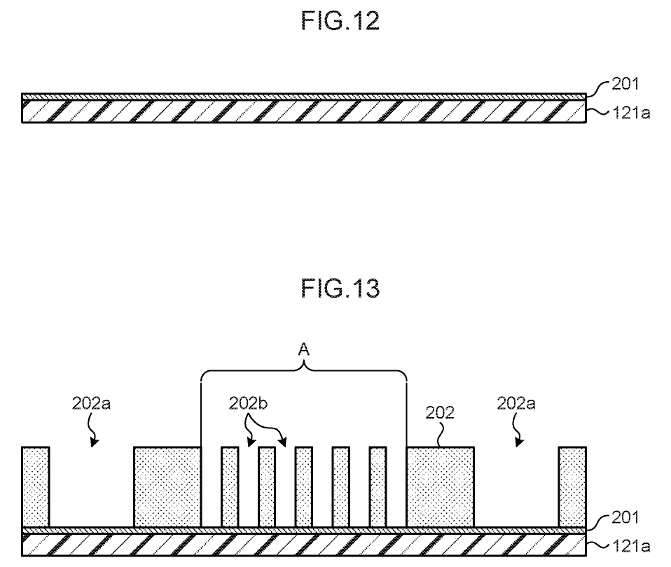

When the insulating layer 121a has been formed, a seed layer is formed on the insulating layer 121a (Step S201). Specifically, for example, as illustrated in FIG. 12, a seed layer 201 is formed on the upper surface of the insulating layer 121a by performing, for example, electroless copper plating. FIG. 12 is a diagram illustrating a specific example of the seed layer forming step. The thickness of the seed layer 201 is, for example, 1 pm, and is within a range of 0.5 to 1.5 pm.

Then, a dry film resist (DFR) is laminated on the seed layer 201 (Step S202), a process of exposure and image development is performed in accordance with the positions of the pad 124 and the plurality of wiring patterns 125 (Step 5203). Moreover, a DFR 202 is made of an insulating resin having a photosensitive property. As a result of this, for example, as illustrated in FIG. 13, opening portions 202a and 202b are formed at a position at which the pad 124 and the plurality of wiring patterns 125 for the DFR 202 that is laminated on the seed layer 201 are formed. FIG. 13 is a diagram illustrating a specific example of an image development step. At this step, the opening portion 202a having a relatively large width is formed at the DFR 202, and, furthermore, the plurality of opening portions 202b that have a relatively small width are formed side by side in the predetermined area A that is sandwiched between the pair of opening portions 202a provided at the DFR 202. Moreover, the thickness of the DFR 202 is about, for example, 20 to 30 pm

new paragraph...

Then, by performing, for example, electrolytic copper plating (Step S204), the pad 124 is formed at the opening portion 202a of the DFR 202, and also, the plurality of wiring patterns 125 are formed at the plurality of respective opening portions 202b provided at the DFR 202. At this time, the composition of a copper sulfate plating solution that is used for electrolytic copper plating is, for example, as follows:

copper sulfate: 200 g/L

sulfuric acid: 130 g/L chloride ion: 37.5 ppm

leveler: 2.0 mL/L

Moreover, a copper sulfate plating solution may further contain brightener (accelerating agent). Furthermore, in a case where brightener (accelerating agent) is not contained in the copper sulfate plating solution, a pre-dip process for applying brightener (accelerating agent) to the seed layer 201 that is exposed from the opening portions 202a and 202b may be performed before a process of electrolytic copper plating using the copper sulfate plating solution is performed. The pre-dip process is performed by immersing the seed layer 201 that is exposed from the opening portions 202a and 202b in a chemical solution that is obtained by adding 0.5 g/L of brightener (accelerating agent) to a 5% sulfuric acid solution at a temperature of 25°C for 265 seconds.

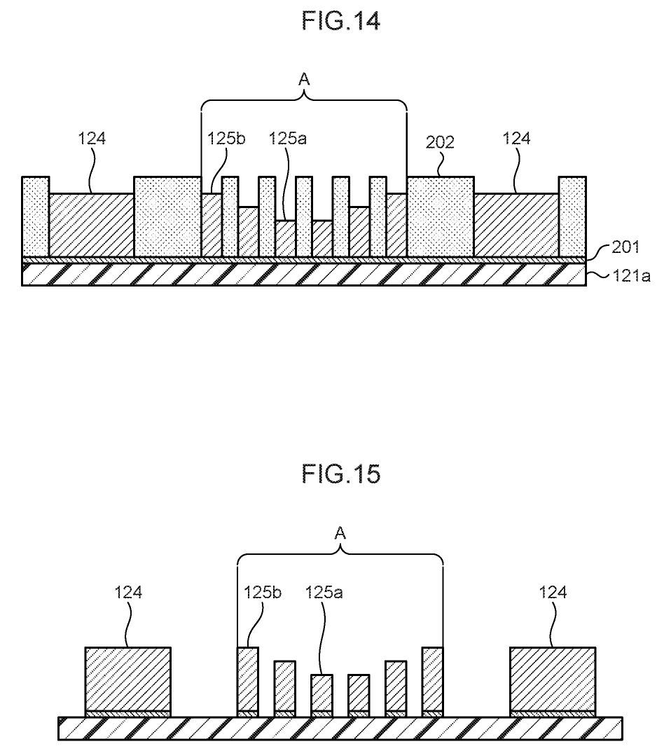

By performing electrolytic copper plating at a predetermined electric current density for a predetermined time by using the copper sulfate plating solution as described above, copper is deposited to the opening portions 202a and 202b, and then the pad 124 and the plurality of wiring patterns 125 are formed. In this case, by performing electrolytic copper plating at an electric current density that is greater than the electric current density in the case where the heights of the plurality of wiring patterns 125 are the same, for example, as illustrated in FIG. 14, the plurality of wiring patterns 125 that are higher in height at both end portions of the predetermined area A and that are lower in height at the central portion of the predetermined area A are formed. FIG. 14 is a diagram illustrating a specific example of a plating step. Line and space (L/S) patterns of the plurality of wiring patterns 125 may be set to about 7/8 pm. Furthermore, in a process of electrolytic copper plating, the electric current density that is greater than the electric current density in the case where the heights of the plurality of wiring patterns 125 are the same may be set to, for example, about 2.5 ASD (A/dm2).

Here, the reason that the plurality of wiring patterns 125 that are higher in height at both end portions of the predetermined area A and that are lower in height at the central portion of the predetermined area A are formed is as follows. Namely, the width of the opening portion 202a in which the pad 124 is formed is larger than the width of each of the plurality of opening portions 202b in which the plurality of respective wiring patterns 125 are formed, so that the electric current flowing toward the opening portion 202a is larger than the electric current flowing toward the plurality of opening portions 202b. Furthermore, the electric current flowing toward the plurality of opening portions 202b decreases as the electric current flows away from the opening portion 202a. As a result of this, as compared with the both end portions of the predetermined area A that is sandwiched by the pair of opening portions 202a, a plating deposition amount decreases at the central portion of the predetermined area A. As a result of this, the wiring patterns 125a that are arranged at the central portion of the predetermined area A are lower than the wiring patterns 125b that are arranged at the both end portions of the predetermined area A. This tendency becomes more pronounced as the electric current density of electrolytic plating increases.

Moreover, a process of reverse electrolysis pulse plating may also be performed as the electrolytic copper plating. At this time, by using the copper sulfate plating solution as described above, the process of reverse electrolysis pulse plating is performed under the plating condition that, for example, an electric current density is 2.5 ASD (A/dm²), a positive electrolysis time is 280 milliseconds, a reverse electrolysis time is 10 milliseconds, a bath temperature is 45°C, a plating time is 1384 seconds. Also under such a condition, copper is deposited to the opening portions 202a and 202b, and then, the pad 124 and the plurality of wiring patterns 125 are formed. At this time, the plurality of wiring patterns 125 that are higher in height at both end portions of the predetermined area A and that are lower in height at the central portion of the predetermined area A are formed.

When the pad 124 and the plurality of wiring patterns 125 have been formed, the DFR 202 is stripped off (Step S205). In order to strip off the DFR 202, for example, sodium hydroxide or an amine-based alkaline stripping solution is used. As a result of the DFR 202 being stripped off, the wiring layer 122 that is in a state in which the pad 124 and the plurality of wiring patterns 125 are formed on the seed layer 201 is obtained. At this stage, the seed layer 201 remains the entire surface, and the pad 124 and the plurality of wiring patterns 125 are short-circuited, so that there is a need to remove the seed layer 201 disposed at a position that is an unneeded portion and that does not overlap with the pad 124 and the plurality of wiring patterns 125.

Accordingly, an etching process is performed on the seed layer 201 by using the pad 124 and the plurality of wiring patterns 125 as a mask (Step S206). Specifically, for example, as illustrated in FIG. 15, the seed layer 201 that has been formed on the upper surface of the insulating layer 121a is immersed in an etching solution that selectively dissolves, for example, copper, so that the seed layer 201 disposed at a position that is an unneeded portion and that does not overlap with the pad 124 and the plurality of wiring patterns 125 are removed. As a result of this, the wiring layer 122 that includes both of the pad 124 and the plurality of wiring patterns 125 that are formed side by side in the predetermined area A sandwiched between the pair of pads 124 and that have an occupied area smaller than that of the pad 124 is formed. FIG. 15 is a diagram illustrating a specific example of the etching step.

As described as above, a wiring substrate according to the embodiment (as one example, the wiring substrate 100) includes a wiring layer (as one example, the wiring layer 122) and an insulating layer (as one example, the insulating layers 121 and 121b). The wiring layer includes a conductor pattern (as one example, the pad 124), and a plurality of wiring patterns (as one example, the wiring patterns 125) that are formed side by side in a predetermined area (as one example, the predetermined area A) that is sandwiched between a pair conductor patterns and that have a smaller occupied area than the conductor pattern. The insulating layer is laminated on the wiring layer. The plurality of wiring patterns are formed such that the heights of the wiring patterns (as one example, the wiring patterns 125a) that are arranged at the central portion of the predetermined area are lower than the heights of the wiring patterns (as one example, the wiring patterns 125b) that are arranged at both end portions of the predetermined area. As a result of this, it is possible to suppress a variation in thickness of the insulating layers that cover the wiring layer.

Moreover, according to the embodiment described above, it is assumed that the predetermined area A in which the plurality of wiring patterns 125 are formed is sandwiched by the pair of pads 124, but the pair of conductor patterns that sandwiches the predetermined area A is not limited to the pair of pads 124. Such conductor patterns may also be, for example, a ground plane or a power plane having a planar shape.

According to one aspect of an embodiment of the wiring substrate disclosed in the present application, an advantage is provided in that it is possible to suppress a variation in thickness of the insulating layers that cover the wiring layer.

(Note) (1) A method of manufacturing a wiring substrate comprising:

forming a wiring layer that includes a conductor pattern and a plurality of wiring patterns that are formed side by side in a predetermined area sandwiched between a pair of the conductor patterns and that have a smaller occupied area than the conductor pattern; and laminating an insulating layer on the wiring layer, wherein the forming the wiring layer includes making heights of the wiring patterns that are formed at a central portion of the predetermined area lower than heights of the wiring patterns that are formed at both end portions of the predetermined area among the plurality of wiring patterns.

All examples and conditional language recited herein are intended for pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although the embodiment of the present invention has been described in detail, it should be understood that the various changes, substitutions, and alterations could be made hereto without departing from the spirit and scope of the invention.

What is claimed is:

1. A wiring substrate comprising:a wiring layer that includes a conductor pattern, anda plurality of wiring patterns that are formed side by side in a predetermined area sandwiched between a pair of the conductor patterns and that have a smaller occupied area than the conductor pattern; andan insulating layer that is laminated on the wiring layer, wherein,among the plurality of wiring patterns, heights of the wiring patterns that are arranged at a central portion of the predetermined area are lower than heights of the wiring patterns that are arranged at both end portions of the predetermined area.

2. The wiring substrate according to claim 1, wherein, among the plurality of wiring patterns, a distance between the adjacent wiring patterns is smaller than a distance between each of the wiring patterns that are arranged at the both end portions of the predetermined area and each of the pair of conductor patterns that sandwiches the predetermined area.

3. The wiring substrate according to claim 1, further comprising:another wiring layer that is laminated on the insulating layer, anda via that passes through the insulating layer, wherein the conductor pattern is a pad that is connected to the another wiring layer by way of the via.

4. The wiring substrate according to claim 1, wherein the conductor pattern is a ground plane or a power plane that has a planar shape.
